(19) United States
(12) Patent Application Publication
(10) Pub. No.: US 2020/0194955 A1
(43) Pub. Date: Jun. 18, 2020

(54) Narrowband Pump module for Diode Pumped Alkali Vapors

(71) Applicant: Government of the United States as represented by the Secretary of the Air Force, Wright-Patterson AFB, OH (US)

(72) Inventors: Matthew Rotondaro, Colorado Springs, CO (US); Boris Zhdanov, Colorado Springs, CO (US); Michael Shaffer, Centennial, CO (US); Randal Knize, Colorado Springs, CO (US)

(21) Appl. No.: 16/217,200

(22) Filed: Dec. 12, 2018

(51) Int. Cl. H01S 3/03; H01S 5/20; H01S 5/14; H01S 3/227; H01S 3/0941; H01S 3/08; H01S 3/10; H01S 3/106; H01S 3/06; H01S 5/40

(52) U.S. Cl. CPC H01S 3/031; H01S 5/2036; H01S 5/142; H01S 3/227; H01S 5/4025; H01S 3/08054; H01S 3/10061; H01S 3/1066; H01S 3/0621; H01S 3/0941

(57) ABSTRACT

A narrow-band diode pumped alkali laser (DPAL) comprising a diode emitter assembly of broad area diode lasers arranged in a stack or array to emit longitudinally at a power level in a power range of 10-1500 W through a frequency selective element assembly aligned and positioned in an external laser cavity to the diode emitter assembly. The frequency selective element assembly comprising: an optical cell containing alkali vapor positioned between a pair of crossed polarizers; a partially reflective mirror that reflects a portion of light passing through the optical cell back toward the diode emitter assembly; and magnetic field producing components that produce a magnetic field through the optical cell that creates a 90° polarization of light passing through the optical cell at a narrow-band frequency corresponding to the absorption line of alkali atom, attenuating components of the light passing through the optical cell at frequencies outside of the narrow-band frequency.

### CROSS-REFERENCE TO RELATED APPLICATIONS

This application claims the benefit of priority under 35 U.S.C. § 119(e) to U.S. Provisional Applications: (i) Ser. No. 62/614,729 entitled “Narrowband Pump Module for Diode Pumped Alkali Lasers,” [Docket AFD-1780P] filed 8 Jan. 2018; (ii) Ser. No. 62/616,090 entitled “Narrowband Pump Module for Diode Pumped Alkali Vapors,” [Docket AFD-1780P2] filed 11 Jan. 2018; and (iii) Ser. No. 62/773,371 entitled “Narrowband diode laser pump module for pumping alkali vapors”, [Docket AFD-1780P3], filed 30 Nov. 2018, the contents of all three of which are incorporated herein by reference in their entirety.

### ORIGIN OF THE INVENTION

The invention described herein was made by employees of the United States Government and may be manufactured and used by or for the Government of the United States of America for governmental purposes without the payment of any royalties thereon or therefore.

### BACKGROUND

### 1. Technical Field

The present disclosure generally relates to apparatus and methods of generating narrowband, high power laser light, and more particularly of generating narrowband, high power laser light that are narrowband frequency controlled by magneto-optical Faraday effect.

### 2. Description of the Related Art

High power diode lasers, and diode laser stacks, are spectrally broad band (about 1 THz) and certain applications require narrowing to approximately 10-20 GHz while maintaining high power and high speed (microsecond) turn on time and being in resonance with the alkali atom n²S_{1/2}→n²P_{3/2} or the n²S_{1/2}→n²P_{1/2} transition.

Prior art methods use either a volume Bragg grating (VBG) or less commonly a diffraction grating in an external cavity geometry to narrow the line width of the diode laser output radiation and to select the operating frequency that matches absorption line of an alkali atom. The problem with these methods is that there is no absolute reference for the operation frequency and tuning to a desired frequency is generally accomplished using electronic feedback loops to adjust the tuning element angle (diffraction grating) or temperature (VBG).

Furthermore, for VBGs the frequency is adjusted by tuning the temperature of the VBG which has to be locked with high precision (about 0.5° C.) to maintain resonance to the absorption line of the alkali atom. This adjustment and frequency locking must be accomplished for each and every diode emitter in a bar or stack, in which there can contain hundreds. This problem is exacerbated by the thermal change of the VBG or diffraction grating when the diode is turned on and off because of light absorbed by the element. The VBG or diffraction grating will heat when the diode is turned on and cools when the diode is turned off, causing the operating frequency to vary with temperature. Additionally, line broadening in VBG or diffraction grating performance may be experienced due to temperature gradients across the element. Therefore, even with very aggressive thermal control, the frequency shift and broadening can be significant during the turn-on of the diode pump source. The temperature will eventually stabilize after several minutes of operation.

Commercially available devices and methods for diode laser line narrowing and frequency selection uses VBGs on each of the diode bars. Diodes line narrowed and frequency locked using VBGs can be purchased off-the-shelve from Coherent/Dilas. The problem with this method is that there is no absolute reference for the frequency locking and tuning must be accomplished via electronic feedback loops. The frequency is selected by adjusting the temperature of the VBG. This adjustment must be accomplished for each and every diode emitter. Since each VBG must have its temperature adjusted individually, there is a variation in frequency. This frequency variation broadens the aggregate emission line width of the diode laser and acts against the desire to narrow the line width which is the point of using the VBG. The resulting line width is on the order of 100 GHz or more. This problem is exacerbated by the thermal change and thermal gradients in the VBG when the diode laser is turned on and off. The VBG heats when the diode is turned on and cools when the diode is turned off. Therefore, even with very aggressive thermal control, the frequency can shift significantly during the turn-on of the diode pump source. The temperature will eventually stabilize after several minutes of operation but for many applications minutes are too long a turn-on time.

### BRIEF SUMMARY

Uses of magneto-optical Faraday effect for narrowband control of laser light was generally known for lower power laser light. Consistent teachings in the art required that alkali vapor cells used to create the magneto-optical Faraday Effect had to operate at a low power that would not create a disturbance. The present innovation recognized an opportunity to use improved alkali vapor cells at power levels several magnitudes greater than what had been demonstrated and analyzed during the preceding few decades. Applicants discovered that magneto-optical Faraday Effect could be made to work even with high power levels that create a disturbance in the alkali vapor cell. In particular, the present disclosure provides efficiently pumping an alkali vapor. Embodiments of the disclosed pump module simultaneously achieve all of these requirements and offers significant advantages over current technology with a narrowband pump module for diode pumped alkali vapors.

In one aspect, the present disclosure provides a narrow-band diode pumped alkali laser (DPAL) pump module that includes a diode emitter assembly and a frequency selective element. The diode emitter assembly includes a plurality of broad area diode lasers arranged in a selected one of: (i) a stack; and (ii) an array to emit longitudinally at a power level in a power range of 10-1500 W. The frequency selective element assembly is aligned and positioned in an external laser cavity to the diode emitter assembly. The frequency selective element assembly includes a pair of crossed polarizers. The frequency selective element assembly includes an optical cell containing alkali vapor positioned between the pair of crossed polarizers. The frequency selective element assembly includes a partially reflective mirror that reflects a portion of light passing through the optical cell back toward the diode emitter assembly. The frequency selective element assembly includes magnetic field producing components that produce a magnetic field through the optical cell that creates a 90° polarization of light passing through the optical cell at a selected narrow-band frequency corresponding to the absorption line of alkali atom, attenuating components of the light passing through the optical cell at frequencies outside of the narrow-band frequency.

In another aspect, the present disclosure provides a method of producing high-power, narrow-band laser light with a DPAL pump module. In one or more embodiments, the method includes energizing a diode emitter assembly to emit at a power level in a power range of 10-1500 W, the diode emitter assembly comprising a plurality of broad area diode lasers arranged in a selected one of: (i) a stack; and (ii) an array arranged to emit longitudinally. The method includes maintaining a temperature and a magnetic field along an optical cell containing alkali vapor of a frequency selective element assembly, which is aligned and positioned in an external laser cavity to the diode emitter assembly sufficient to create a 90° polarization of light passing through the optical cell at a selected narrow-band frequency corresponding to the absorption line of alkali atom, attenuating components of the light passing through the optical cell at frequencies outside of the narrow-band frequency. The frequency selective element comprises (i) a pair of crossed polarizers; (ii) the optical cell positioned between the pair of crossed polarizers; (iii) a partially reflective mirror that reflects a portion of light passing through the optical cell back toward the diode emitter assembly; and (iv) magnetic field producing components that produce a magnetic field through the optical cell that creates a 90° polarization of light passing through the optical cell at a selected narrow-band frequency corresponding to the absorption line of alkali atom, attenuating components of the light passing through the optical cell at frequencies outside of the narrow-band frequency.

The above summary contains simplifications, generalizations and omissions of detail and is not intended as a comprehensive description of the claimed subject matter but, rather, is intended to provide a brief overview of some of the functionality associated therewith. Other systems, methods, functionality, features and advantages of the claimed subject matter will be or will become apparent to one with skill in the art upon examination of the following figures and detailed written description.

### BRIEF DESCRIPTION OF THE DRAWINGS

The description of the illustrative embodiments can be read in conjunction with the accompanying figures. It will be appreciated that for simplicity and clarity of illustration, elements illustrated in the figures have not necessarily been drawn to scale. For example, the dimensions of some of the elements are exaggerated relative to other elements. Embodiments incorporating teachings of the present disclosure are shown and described with respect to the figures presented herein, in which:

FIG. 1 is a diagram illustrating a narrow-band diode pumped alkali laser (DPAL) pump module, according to one or more embodiments;

FIG. 2 is a graphical plot illustrating spectrum of the diode laser stack emission with and without the Faraday filter, according to one or more embodiments;

FIG. 3 is a graphical plot illustrating high resolution spectrum of the line narrowed diode laser stack reveals a bimodal distribution, according to one or more embodiments;

FIG. 4 is a graphical plot illustrating a low intensity Faraday filter transmission spectrum along with the transmission of the cesium vapor cell without the polarizers, according to one or more embodiments;

FIG. 5 is a graphical plot wherein triangles indicate the power output of the diode stack in an external cavity without the Faraday filter and circles show the narrow-banded pump module output power versus input current, according to one or more embodiments; and

FIG. 6 illustrates a method of generating narrow-band, high-power laser light that rapidly stabilizes, according to one or more embodiments.

### DETAILED DESCRIPTION

During the past decade, Diode Pumped Alkali Lasers (DPALs) have received significant attention [References 1-5] because DPALs combine many positive features of gas lasers and diode pumped solid state lasers. The DPAL has the feature of being electrically excited using a diode laser similar to solid state lasers but has the heat management and inherent good beam quality of a gas phase laser. In recent years, DPALs have demonstrated high average power of 1.5 kW [References 6] and showed great promise for future power scaling. In addition to the experimental efforts, there has been significant effort in the theoretical analysis of DPALs [References 7-8]. A key element of any DPAL is the diode laser pump module. The current state-of-the-art pump module is a Volume Bragg Grating (VBG) line narrowed diode laser bar or stack [References 9-13]. The problem with using multiple VBGs, required for narrowbanding stacks, is the requirement to be individually tuned to the resonant frequency. Also, they have an inherently broad line width of about 0.3 nm, which is about an order of magnitude broader than the alkali absorption line broadened by one atmosphere (atm) buffer gas. An alternative method used for line narrowing of low power single emitter diodes is to use a Faraday filter which has been demonstrated by [References 14-25]. In the present disclosure, Applicant demonstrates the first high power line narrowing of a 600 watt diode laser stack to the linewidth of 10 GHz and locking this line to the 6²S_{1/2}→6²P_{3/2} transition of Cs atom using a Faraday filter in an external cavity of a diode pump module.

In one or more embodiments, a diode pumped alkali laser (DPAL) includes a diode emitter assembly, which is a laser stack or diode array consisting of multiple broad area diode lasers frequency locked to the atomic resonance of alkali atomic vapor. The laser emitter assembly outputs laser light of a power level in a range of 10-1500 W. The DPAL includes an external laser cavity for the diode stack or array containing a frequency sensitive element and a partially reflecting mirror that is used to lock stack or array frequency to the alkali atomic resonance. The frequency selective element installed into the diode stack external cavity includes an optical cell containing low pressure alkali metal vapor, one or more magnets that create a magnetic field inside the cell and crossed polarizers located before and after the cell. The magnetic field created by the magnets can be oriented parallel, crossed or at an arbitrary angle to the propagation of the light from the diode stack and the field strength can range from 50 to 2000 Gauss and has to create a 90 degree polarization rotation for a narrowband light frequency corresponding to the absorption line of the alkali atom. The alkali vapor cell length is chosen such as to provide a 90 degree polarization rotation for used magnetic field strength and cell temperature. In one or more embodiments, the alkali vapor cell length is in a range of 1 to 30 cm.

The alkali vapor behaves differently at high power than theory predicts at low power. The temperature range is power dependent. For example, with cesium at low power (1-100 mW) and with a magnetic field of about 300 Gauss, the optimal temperature would be about 53 C because this would give optimal transmission through the filter at an optimal wavelength. At high power (greater than 1 W), the filter would just stop working but by raising the temperature of the cell the filter will start working again because of the increase in cesium number density. Now, if one did a generally-known and accepted analysis of the Faraday cell at the higher temperature, the optimal transmission wavelength predicted would not be the wavelength that the diode emitter assembly would actually be locked to. As the power of the diode module is increased, the temperature of the Faraday cell must also be increased otherwise, the filter will just stop working. The present disclosure recognizes that this increasing of both power and temperature is not unlimited. At some point, the temperature gets high enough that the filter will become unstable and also stop working. The filter cell with very high power and high temperature will no longer work as a filter, but will start to glow like a lightbulb. The challenge is understanding this trade-off space between cell temperature and laser power to achieve a working line narrowed frequency locked pump module. This is behavior is non-intuitive and is not described by the general theory that describes low power Faraday filters.

Increases in the length of the alkali vapor cell enables the DPAL to operate at high power levels. In theory, the cell length, cell temperature, and the magnetic field can be traded off to produce the same performance. For example, a short cell with a moderate temperature and a high magnetic field would operate as well as a short cell with a high temperature and a moderate magnetic field. To achieve the high power level, what is needed is a long cell length, high temperature, and high magnetic field. Limits on magnetic field are dependent on the choice of alkali metal. For example, magnetic fields above 1000 Gauss used for cesium will cause degradation of performance due to Zeeman splitting. By contrast, a magnetic field up to at least 1500 Gauss is acceptable for sodium. Producing a magnetic field greater than 1000 Gauss is also technically challenging. Producing a magnetic field greater than 2000 Gauss is technically very difficult.

In one or more embodiments, A DPAL pump module includes a laser emitter assembly; DPAL pump module includes an external laser cavity having a frequency sensitive element that causes an anti-reflection coated output facet of the laser emitter assembly to lase, the frequency sensitive element comprising: (i) a first linear polarizer; (ii) an alkali vapor cell containing alkali vapor mixed with a buffer gas; (iii) and a second linear polarizer having a polarization that 90 degrees different from the first linear polarizer. DPAL pump module includes an output coupler that receives output from the external laser cavity. One or more magnets create a magnetic field across the frequency sensitive element having a magnetic field strength that creates a 90 degree polarization across the length of the alkali vapor cell of a narrowband frequency that will lase, The diode emitter assembly generates output power above a threshold sufficient for optical pumping of ground state atoms of alkali in the alkali vapor cell that result in an effective reduction of alkali number density moving two transmission peaks towards a center with sufficient gain to both lase simultaneously.

In the following detailed description of exemplary embodiments of the disclosure, specific exemplary embodiments in which the disclosure may be practiced are described in sufficient detail to enable those skilled in the art to practice the disclosed embodiments. For example, specific details such as specific method orders, structures, elements, and connections have been presented herein. However, it is to be understood that the specific details presented need not be utilized to practice embodiments of the present disclosure. It is also to be understood that other embodiments may be utilized and that logical, architectural, programmatic, mechanical, electrical and other changes may be made without departing from general scope of the disclosure. The following detailed description is, therefore, not to be taken in a limiting sense, and the scope of the present disclosure is defined by the appended claims and equivalents thereof.

References within the specification to “one embodiment,” “an embodiment,” “embodiments”, or “one or more embodiments” are intended to indicate that a particular feature, structure, or characteristic described in connection with the embodiment is included in at least one embodiment of the present disclosure. The appearance of such phrases in various places within the specification are not necessarily all referring to the same embodiment, nor are separate or alternative embodiments mutually exclusive of other embodiments. Further, various features are described which may be exhibited by some embodiments and not by others. Similarly, various requirements are described which may be requirements for some embodiments but not other embodiments.

It is understood that the use of specific component, device and/or parameter names and/or corresponding acronyms thereof, such as those of the executing utility, logic, and/or firmware described herein, are for example only and not meant to imply any limitations on the described embodiments. The embodiments may thus be described with different nomenclature and/or terminology utilized to describe the components, devices, parameters, methods and/or functions herein, without limitation. References to any specific protocol or proprietary name in describing one or more elements, features or concepts of the embodiments are provided solely as examples of one implementation, and such references do not limit the extension of the claimed embodiments to embodiments in which different element, feature, protocol, or concept names are utilized. Thus, each term utilized herein is to be given its broadest interpretation given the context in which that terms is utilized.

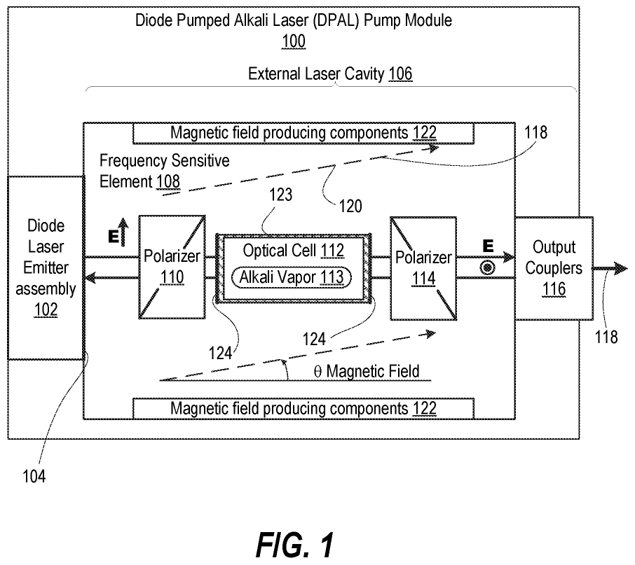

FIG. 1 is a diagram illustrating diode pumped alkali laser (DPAL) pump module 100. DPAL pump module 100 includes laser emitter assembly 102 that includes a plurality of broad area diode lasers arranged in a selected one of: (i) a stack; and (ii) an array to emit longitudinally at a power level in a power range of 10-1500 W. Diode emitter assembly 102 includes an anti-reflection coated output facet 104, which is configured to lase across an external laser cavity 106 containing a frequency sensitive element 108. Frequency sensitive element 108 is aligned and positioned to provide optical feedback to diode emitter assembly 102 to create narrow-band frequency. Described from proximal to distal to diode emitter assembly 102, frequency sensitive element 108 includes first linear polarizer 110, optical cell 112 containing alkali vapor 113, and second linear polarizer 114. The pair of first and second linear polarizers 110, 114 are cross polarized. Outputs of frequency sensitive element 108 pass through output coupler, which is a partially reflective mirror (output coupler) 116, as narrowband, higher power laser light 118. Output coupler 116 has reflectivity in the range of about 10-90% depending on diode laser design and losses in external laser cavity 106. The narrowband nature of laser light 118 is achieved with a magnetic field 120 of polarization “θ” created by permanent or electro magnets within external laser cavity 106 as magnetic field producing components 122. Magnetic field producing components 122 that produce magnetic field 120 through optical cell 112 create a 90° polarization of light passing through optical cell 112 at a selected narrow-band frequency corresponding to the absorption line of alkali atom, attenuating components of the light passing through optical cell 112 at frequencies outside of the narrow-band frequency.

Embodiments of the present disclosure demonstrate high speed turn-on (less than 10 microseconds), frequency locked to the atomic resonance and narrow line width (about 10 GHz). This new method uses magneto optical scattering filters to simultaneously lock all of the diodes of diode emitter assembly 102 to the same atomic transition as alkali vapor pump line. Because the frequency is locked to the atomic transition, the resulting line width is narrowed to about 10 GHz. Also, this locking technique ensures diodes of diode emitter assembly 102 are always on resonance with the alkali atomic line of optical cell 112 even while going through thermal fluctuations during turn-on. Ultimately, this results in DPAL pump module 100 that can be turned on in only a few microseconds and is locked to the atomic resonance with a spectral line width of −10 GHz.

DPAL is a laser that uses an alkali metal vapor (sodium, potassium, rubidium or cesium) mixed with a buffer gas as the gain medium. For each of these lasers of a particular alkali species, a diode laser such as diode emitter assembly 102 is used to pump the n²S_{1/2}→n²P_{3/2} transition, where n is the principle quantum number for an alkali. The spectral line width of the pump transitions is commonly pressure broadened to 10 to 20 GHz via a buffer gas. The buffer gas serves to mix the ground state hyperfine levels and to quickly transfer the population from the n²P_{3/2} level to the n²P_{1/2} level. Once the population is transferred to the n²P_{1/2} level and population inversion is achieved, it can produce gain and achieve stimulated emission on the n²P_{1/2}→n²S_{1/2} transition. In order to efficiently pump the n²S_{1/2}→n²P_{3/2} transition the DPAL pump source (diode emitter assembly 102) must be spectrally matched to this transition. An optimized pump source would be frequency locked to the pump transition, have a spectral line width that matches the pressure broadened atomic transition of typically 10-20 GHz and have a rapid turn-on time in the microsecond range. Similarly, for any requirement to pump an alkali vapor such as atomic polarization the pump would be locked to either the n²S_{1/2}→n²P_{3/2} or the n²S_{1/2}→n²P_{1/2} atomic transition.

In one or more embodiments, DPAL pump module 100 has an emission spectrum perfectly and automatically matches the alkali metal atomic transition without using any control devices. According to the present disclosure DPAL pump module 100 also has narrowband emission line which are well matched to the ˜10 GHz gain medium absorption line significantly increasing DPAL pumping efficiency. The method of line narrowing and frequency locking described herein has significant advantages over prior art methods. This is because this method of frequency locking uses the atomic pump level transition to lock the diode frequency. Therefore, the frequency lock for all diodes of DPAL diode emitter assembly 102 is exactly in resonance with the pressure broadened laser line. Additionally, this method also narrows the line shape of the diode emitter assembly 102 resulting in a pump line width on the order of 10-20 GHz; which is significantly less than the 100 GHz achieved by the current method.

The frequency sensitive element may be an optical cell 112 placed in a magnetic field between two linear polarizers 110, 114. Crossed polarizers 110, 114 are oriented such that the polarization of second linear polarizer 114 is rotated 90 degrees relative to first linear polarizer 110. Output coupler 114 of external laser cavity 106 Magnetic field 118 is applied to optical cell 112 using either permanent or electro magnets as magnetic field producing components 122. Magnetic field 120 causes a rotation of the laser light polarization and can be applied at any angle θ relative to the laser cavity optical axis. This rotation is illustrated by vertically polarized e-field between diode emitter assembly 102 and first linear polarizer 110; horizontally polarized e-field is between second linear polarizer 114 and output coupler 116. The case where the angle θ=0 may be referred to as a Faraday configuration, and the case where the angle θ=90 degrees may be referred to as a Voigt configuration. The narrowbanding occurs because only the spectral components of the diode laser emission which match the alkali atomic transition n²S_{1/2}→n²P_{3/2} or n²S_{1/2}→n²P_{1/2} of whatever alkali is present in the alkali vapor cell 110 can be transmitted by this magneto-optical filter and serve as feedback to the emitters in the diode emitter assembly 102. For the best performance, the magnetic field strength should be chosen such that the rotation of the polarization of the desired frequency is an optimal 90 degrees. All other spectral components will not experience this rotation in polarization, have significant losses and will not lase. That means that lasing occurs only in narrow spectral range corresponding to the pressure broadened alkali gain medium (about 10 GHz).

The alkali vapor cell requires special manufacturing requirements, and currently available cells will not tend to produce acceptable results. Alkali vapor optical cell 112 consists of a quartz cylinder 123 with anti-reflective coated windows 124 attached to each end. Optical cell 112 is then evacuated to approximately 10⁻⁶ Torr. Optical cell 112 then has approximately 0.1 grams of alkali metal added and is then sealed.

Before DPAL pump module 100 can be used, alkali vapor optical cell 112 must be heated to a temperature between about 50 and about 200 C. The optimal temperature is dependent on the alkali metal chosen, the strength of the applied magnetic field (10-2000 Gauss), the length of the alkali vapor cell (usually about 10-30 cm), and the strength of the Verdet and Voigt constants for the transition of interest. Once alkali vapor optical cell 112 has been heated to the optimal temperature, the diode emitter assembly 102 can be turned on and light emitted from output coupler 116 is directed to alkali vapor in alkali vapor optical cell 112 to pump the laser transition. TABLE 1 lists all of the alkali metals and corresponding temperature and magnetic field ranges.

TABLE 1
Temperature and magnetic field ranges for each alkali metal.

| Alkali Metal | Temperature Range C. | Magnetic Field Gauss |
|---|---|---|
| Lithium | 50-500 | 50-2000 |
| Sodium | 50-400 | 50-2000 |
| Potassium | 50-300 | 50-1500 |
| Rubidium | 50-300 | 50-1000 |
| Cesium | 50-250 | 50-1000 |

Embodiments of this DPAL pump module 100 are applicable to the alkali metals sodium, potassium, rubidium and cesium. This also applies to all angles of incident of the diode output to the magnetic field. Alkali vapor optical cell 110 can be any length and can be made from any material that will not react with the alkali vapor such as sapphire, nickel, stainless steel etc. The windows on the vapor cell can also be either anti-reflective coated or Brewster angle windows.

In a demonstrated embodiment, a method is presented of line narrowing and frequency-locking a diode laser stack to an alkali atomic line for use as a diode emitter assembly 102 for DPAL pump module. The diode emitter assembly 102 consists of a 600 W antireflection coated diode laser stack configured to lase using an external cavity. The line narrowing and frequency locking is accomplished by introducing a narrowband polarization filter based on magneto-optical Faraday effect into the external cavity, which selectively transmits only the frequencies that are in resonance with the 6²S_{1/2}→6²P_{3/2} transition of Cs atoms. The resulting diode emitter assembly 102 has demonstrated that a diode laser stack, which lases with a line width of 3 THz without narrowbanding, can be narrowed to 10 GHz. The line narrowed diode emitter assembly produced 518 Watts that is 80% of the power generated by the original broadband diode laser stack.

Experimental apparatus and results: With continued reference to FIG. 1, the method of line narrowing and frequency-locking a diode laser stack to an alkali atomic line for use as a diode emitter assembly for diode pumped alkali lasers was demonstrated by Applicant. DPAL diode emitter assembly 102 consists of a 600 W antireflection coated diode laser stack configured to lase using an external cavity. The line narrowing and frequency locking is accomplished by introducing a narrowband polarization filter based on magneto-optical Faraday effect into the external cavity, which selectively transmits only the frequencies that are in resonance with the 6²S_{1/2}→6²P_{3/2} transition of Cs atoms. The resulting DPAL pump module 100 has demonstrated that a diode laser stack, which lases with a line width of 3 THz without narrowbanding, can be narrowed to 10 GHz. The line narrowed pump module produced 518 Watts that is 80% of the power generated by the original broadband diode laser stack.

According to aspects of the present disclosure, DPAL pump module 100 was experimentally demonstrated. DPAL pump module 100 consists of a diode laser stack with an antireflection coated output facet, which is configured to lase using an external stable cavity containing a frequency sensitive element. The diode laser stack used was a Dilas 600 W designed to produce light at 852 nm.

The frequency sensitive element is a Faraday filter, which is an alkali vapor cell, 6 inches in length, placed in a magnetic field between two crossed linear polarizers. Output coupler 116 of the external laser cavity had a reflectivity of 20%. Output coupler 116 was flat therefore, to satisfy the cavity stability requirement, a lens with a focal length of 25 cm was placed inside the cavity one focal length away from Output coupler 116. The alkali vapor optical cell 112 was evacuated to pressure of 10⁻⁷ Torr and filled with a visible amount of metallic Cs and was heated to a temperature of 96 C corresponding to a vapor pressure of 1×10¹³/cm³ which provided optimal performance. Optical cell 112 used anti-reflection coated high quality fused silica windows and did not experience any birefringence. A magnetic field of 700 Gauss was applied to the alkali vapor cell using permanent cylindrical neodymium magnets. The magnetic field was applied parallel to the laser cavity optical axis and caused a rotation of the laser light polarization that is in resonance with the cesium 6²S_{1/2}→6²P_{3/2} transition. The narrow-banding occurs because only the polarization of the spectral components of the diode laser emission, which are near the alkali atomic transition 6²S_{1/2}→6²P_{3/2} of the cesium atomic vapor, can be rotated 90° and thus transmitted by this magneto-optical filter in both directions and provide feedback to the emitters in the diode stack. All other spectral components will not experience this rotation of polarization, resulting in significant losses and will not lase. This means that lasing occurs only in a narrow spectral range which matches the Cs 6²S_{1/2}→6²P_{3/2} transition absorption line observed in a 1 atm pressure broadened alkali gain medium (about 12 GHz).

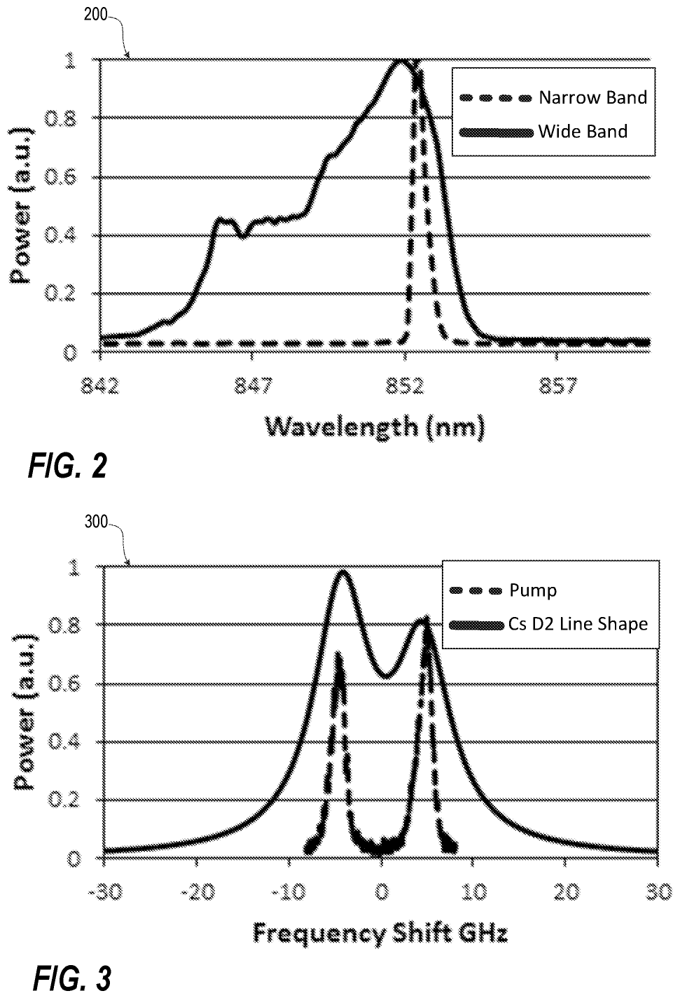

FIG. 2 is a graphical plot 200 illustrating spectrum of the diode laser stack emission with and without the Faraday filter. Applicant examined the spectral output of the unlocked diode laser stack. The spectrum of the unlocked stack was produced by lasing the diode stack using the external cavity but with the Faraday filter removed. The spectrum was recorded using an Ocean Optics USB 2000+ spectrometer with spectral resolution of 2 nm. The unlocked stack lases with a line width of approximately 8 nm or 3 THz (FWHM). Such a broad spectral line is clearly unacceptable for pumping a 20 GHz pressure broadened cesium D2 line. On the other hand, when the Faraday filter is used, then a significant line narrowing occurs as it is also shown in FIG. 2. It should be noted that the line shape of the narrowed line is the instrument function of the Ocean Optics spectrometer and does not provide an accurate representation of the quality of the line narrowing.

FIG. 3 is a graphical plot 300 illustrating high resolution spectrum, recorded with a Fabry-Perot interferometer, of the line narrowed diode laser stack reveals a bimodal distribution. Also shown is the calculated D2 pressure broadened line shape with 200 Torr of methane and 400 Torr of helium. The x-axis is centered on the 6²S_{1/2}→6²P_{3/2} fine structure transition. In order to record this spectrum with sufficient resolution, we used a Burleigh Fabry-Perot interferometer with a free spectral range of 30 GHz and resolution about 0.3 GHz. The recorded spectrum is shown in FIG. 3 together with the Cs D2 pressure broadened line.

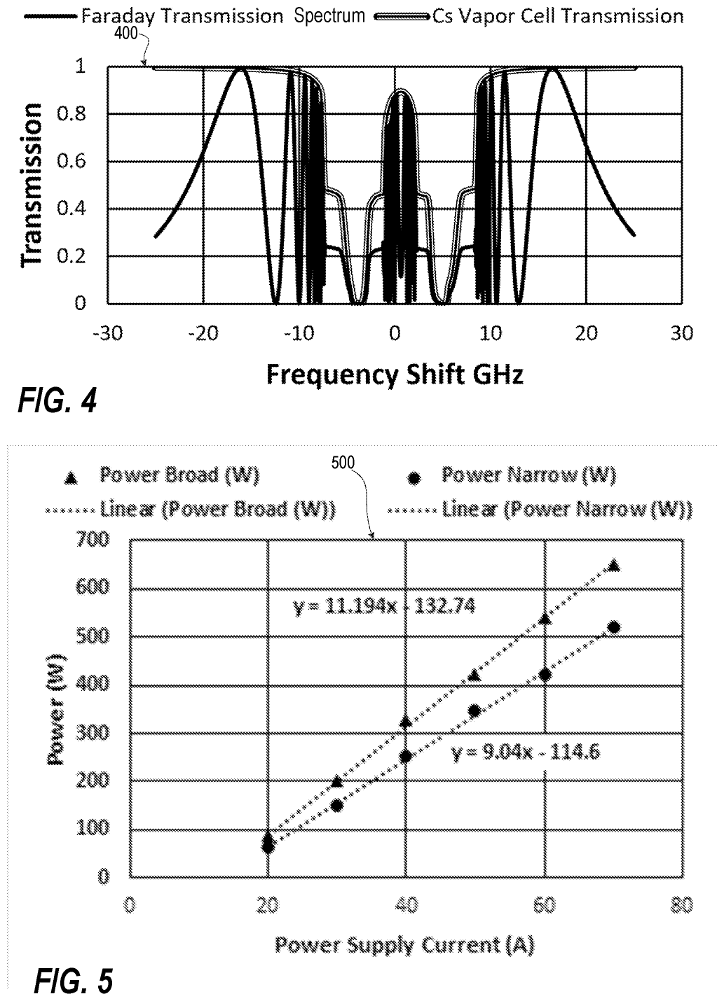

FIG. 4 is a graphical plot 400 illustrating a low intensity Faraday filter transmission spectrum along with the transmission of the cesium vapor cell without the polarizers. The high resolution spectrum shows a bimodal distribution. The pump radiation spectrum is well matched to the Cs D2 line shape pressure broadened using 200 Torr CH₄ and 400 Torr He. The pressure broadened line shape was calculated taking into account the hyperfine splitting of the S and P states using values from Steck [Reference 26] and pressure broadening and line shift reported by Pits [Reference 27]. The low intensity Faraday transmission through the filter is provided in FIG. 4 and was calculated using the methodology outlined in [Reference 28]. The x-axis is centered on the 6²S_{1/2}→6²P_{3/2} fine structure transition.

The calculated Faraday transmission spectrum indicates that the diode stack should frequency lock at approximately ±16 GHz relative to the 6²S_{1/2}→6²P_{3/2} fine structure transition. This would be true in the low intensity limit but at the high powers of this pump module there is significant optical pumping of the ground state atoms resulting in an effective reduction of the alkali number density. This reduction in number density will have the effect of moving the two transmission peaks towards the center. Also, because the diode stack has sufficient gain it will lase simultaneously on both peaks resulting in a bimodal output which quite fortuitously is well matched to a one atmosphere pressure broadened 6²S_{1/2}→6²P_{3/2} transition line shape.

FIG. 5 is a graphical plot 500 wherein triangles indicate the power output of the diode stack in an external cavity without the Faraday filter and circles show the narrow-banded pump module output power versus input current. Also included are the linear least squares fit to the data. The total power output was examined from the narrow-banded diode laser stack pump module. The output power versus power supply current is shown in FIG. 5.

The output power of the pump module appears to be linear with pump current similar to a free running diode stack. The maximum line narrowed power achieved was 518 watts which is about 80% of the broad band value (650 W). Such a loss in narrow-banded output power is expected when introducing losses from optical elements inserted into the external cavity.

In conclusion, DPAL pump module 100 reported in the present disclosure was built using a commercial 600 W diode laser stack originally emitting with broadband radiation with line width about 8 nm. Using a Faraday filter in the external cavity of this stack we succeeded in narrowing spectral line of output radiation of this pump module to the value about 10 GHz, which is well matched to a 12 GHz pressure broadened (1 atm) cesium atomic vapor transition 6²S_{1/2}→6²P_{3/2}. The produced narrowband radiation power was 80% of the stack initial broadband power. This pump module is well matched to the Cs alkali metal pump line and will significantly improve the overall efficiency of a DPAL system. An important feature of this method is that it not only provides significant narrow-banding, but automatically locks the frequency of the pump module to the absorption line of the alkali atom. Such a pump module can also find application in spin-polarization of nuclei such as ³He and ¹²⁹Xe for use in magnetic resonance imaging of lungs and other organs of the human body [References 29, 30].

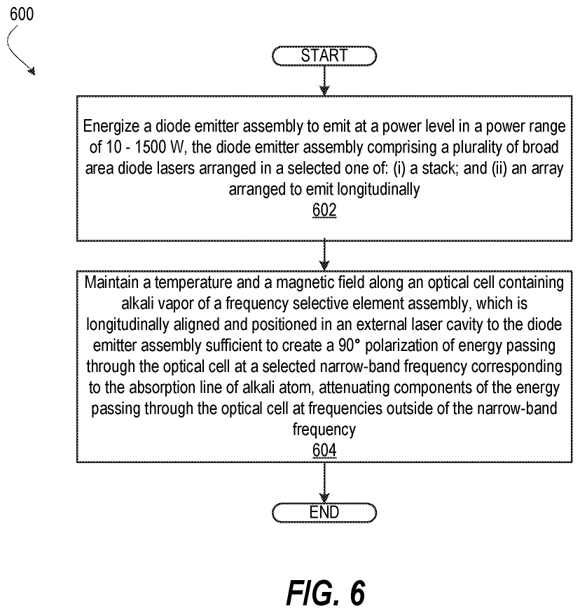

FIG. 6 illustrates a method 600 of generating narrowband, high-power laser light that rapidly stabilizes. In one or more embodiments, method 600 includes energizing a diode emitter assembly to emit at a power level in a power range of 10-1500 W, the diode emitter assembly comprising a plurality of broad area diode lasers arranged in a selected one of: (i) a stack; and (ii) an array arranged to emit longitudinally (block 602). Method 600 includes maintaining a temperature and a magnetic field along an optical cell containing alkali vapor of a frequency selective element assembly, which is aligned and positioned in an external laser cavity to the diode emitter assembly sufficient to create a 90° polarization of light passing through the optical cell at a selected narrow-band frequency corresponding to the absorption line of alkali atom, attenuating components of the light passing through the optical cell at frequencies outside of the narrow-band frequency (block 604). The frequency selective element comprises (i) a pair of crossed polarizers; (ii) the optical cell positioned between the pair of crossed polarizers; (iii) a partially reflective mirror that reflects a portion of light passing through the optical cell back toward the diode emitter assembly; and (iv) magnetic field producing components that produce a magnetic field through the optical cell that creates a 90° polarization of light passing through the optical cell at a selected narrow-band frequency corresponding to the absorption line of alkali atom, attenuating components of the light passing through the optical cell at frequencies outside of the narrow-band frequency.

In one or more embodiments, the magnetic field producing components produce the magnetic field in a range of strength in a range of 50¬2000 Gauss at an angle to propagation of light through the optical cell.

In one or more embodiments, the optical cell comprises a length in a cell length range of 1¬30 cm and is maintained in a temperature range of 50 ¬250° C. with of length, temperature, and magnetic field values selected for pumping the alkali vapor to produce polarized nuclei.

In one or more embodiments, the alkali vapor comprises lithium maintained in a temperature range of 50¬500° C. and the magnetic field in a range of 50¬2000 Gauss.

In one or more embodiments, the alkali vapor comprises sodium maintained in a temperature range of 50¬400° C. and the magnetic field in a range of 50¬2000 Gauss.

In one or more embodiments, the alkali vapor comprises potassium maintained in a temperature range of 50¬300° C. and the magnetic field in a range of 50¬1500 Gauss.

In one or more embodiments, the alkali vapor comprises rubidium maintained in a temperature range of 50¬300° C. and the magnetic field in a range of 50¬1000 Gauss.

In one or more embodiments, the alkali vapor comprises cesium maintained in a temperature range of 50¬250° C. and the magnetic field in a range of 50¬1000 Gauss.

In one or more embodiments, the diode emitter assembly emits at a power level that optically pumps the alkali vapor in the optical cell sufficient to result in an effective reduction of alkali number density moving two transmission peaks towards a center with sufficient gain to both lase simultaneously.

In one or more embodiments, the optical cell comprises two aligned optical windows that are one of: (i) anti-reflective coated; and (ii) Brewster angled to reduce optical losses.

While the disclosure has been described with reference to exemplary embodiments, it will be understood by those skilled in the art that various changes may be made and equivalents may be substituted for elements thereof without departing from the scope of the disclosure. In addition, many modifications may be made to adapt a particular system, device or component thereof to the teachings of the disclosure without departing from the essential scope thereof. Therefore, it is intended that the disclosure not be limited to the particular embodiments disclosed for carrying out this disclosure, but that the disclosure will include all embodiments falling within the scope of the appended claims. Moreover, the use of the terms first, second, etc. do not denote any order or importance, but rather the terms first, second, etc. are used to distinguish one element from another.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The description of the present disclosure has been presented for purposes of illustration and description, but is not intended to be exhaustive or limited to the disclosure in the form disclosed. Many modifications and variations will be apparent to those of ordinary skill in the art without departing from the scope of the disclosure. The described embodiments were chosen and described in order to best explain the principles of the disclosure and the practical application, and to enable others of ordinary skill in the art to understand the disclosure for various embodiments with various modifications as are suited to the particular use contemplated.

1. A narrow-band diode pump module:
a diode emitter assembly comprising a plurality of broad area diode lasers arranged in a selected one of: (i) a stack; and (ii) an array to emit at a power level in a power range of 10¬1500 W; and
a frequency selective element assembly aligned and positioned in an external laser cavity to the pump module, the frequency selective element assembly comprising:
a pair of crossed polarizers;
an optical cell containing alkali vapor positioned between the pair of crossed polarizers;
a partially reflective mirror that reflects a portion of light passing through the optical cell back toward the pump module; and
magnetic field producing components that produce a magnetic field through the optical cell that creates a 90° rotation of the polarization of light passing through the optical cell at a selected narrow-band frequency corresponding to the absorption line of alkali atom, attenuating components of the light passing through the optical cell at frequencies outside of the narrow-band frequency.

2. The narrow-band pump module of claim 1, wherein the magnetic field producing components produce the magnetic field with a strength in a range of 50-2000 Gauss at an angle to propagation of light through the optical cell.

3. The narrow-band pump module of claim 1, wherein the optical cell comprises a length in a cell of 1-30 cm and is maintained in a temperature range of 50-250° C. with of length, temperature, and magnetic field values selected for pumping the alkali vapor to produce electronically excited atoms.

4. The narrow-band pump module of claim 3, wherein the alkali vapor comprises lithium maintained in a temperature range of 50-500° C. and the magnetic field in a range of 50-2000 Gauss.

5. The narrow-band pump module of claim 3, wherein the alkali vapor comprises sodium maintained in a temperature range of 50-400° C. and the magnetic field in a range of 50-2000 Gauss.

6. The narrow-band pump module of claim 3, wherein the alkali vapor comprises potassium maintained in a temperature range of 50-300° C. and the magnetic field in a range of 50-1500 Gauss.

7. The narrow-band pump module of claim 3, wherein the alkali vapor comprises rubidium maintained in a temperature range of 50-300° C. and the magnetic field in a range of 50-1000 Gauss.

8. The narrow-band pump module of claim 3, wherein the alkali vapor comprises cesium maintained in a temperature range of 50-250° C. and the magnetic field in a range of 50-1000 Gauss.

9. The narrow-band pump module of claim 1, wherein the pump module emits at a power level that optically pumps the alkali vapor in the optical cell sufficient to result in an effective reduction of alkali number density moving two transmission peaks towards the atomic line center and has sufficient gain for both lines to lase simultaneously.

10. The narrow-band pump module of claim 1, wherein the optical cell comprises two longitudinally aligned optical windows that are a selected one of: (i) anti-reflective coated; and (ii) Brewster angled to reduce optical losses.

11. A method of producing high-power, narrow-band laser light with a multitude of broadband diode emitters, the method comprising:
energizing a diode emitter assembly to emit at a power level in a power range of 10-1500 W, the diode emitter assembly comprising a plurality of broad area diode lasers arranged in a selected one of: (i) a stack; or (ii) an array arranged to emit longitudinally;
maintaining a temperature and a magnetic field along an optical cell containing alkali vapor of a frequency selective element assembly, which is aligned and positioned in an external laser cavity to the diode emitter assembly sufficient to create a 90° polarization rotation of light passing through the optical cell at a selected narrow-band frequency corresponding to the absorption line of alkali atom, attenuating components of the light passing through the optical cell at frequencies outside of the narrow-band frequency,
wherein the frequency selective element comprises (i) a pair of crossed polarizers; (ii) the optical cell positioned between the pair of crossed polarizers; (iii) a partially reflective mirror that reflects a portion of light passing through the optical cell back toward the diode emitter assembly; and (iv) magnetic field producing components that produce a magnetic field through the optical cell that creates a 90° polarization rotation of light passing through the optical cell at a selected narrow-band frequency corresponding to the absorption line of alkali atom, attenuating components of the light passing through the optical cell at frequencies outside of the narrow-band frequency.

12. The method of claim 11, wherein the magnetic field producing components produce the magnetic field of strength in a range of 50-2000 Gauss at an angle to propagation of light through the optical cell.

13. The method of claim 11, wherein the optical cell comprises of a cell of length ranging from 1-30 cm and is maintained in a temperature range of 50-250° C. with of length, temperature, and magnetic field values selected for pumping the alkali vapor to produce electronically excited atoms.

14. The method of claim 13, wherein the alkali vapor comprises lithium maintained in a temperature range of 50-500° C. and the magnetic field in a range of 50-2000 Gauss.

15. The method of claim 13, wherein the alkali vapor comprises sodium maintained in a temperature range of 50-400° C. and the magnetic field in a range of 50-2000 Gauss.

16. The method of claim 13, wherein the alkali vapor comprises potassium maintained in a temperature range of 50-300° C. and the magnetic field in a range of 50-1500 Gauss.

17. The method of claim 13, wherein the alkali vapor comprises rubidium maintained in a temperature range of 50-300° C. and the magnetic field in a range of 50-1000 Gauss.

18. The method of claim 13, wherein the alkali vapor comprises cesium maintained in a temperature range of 50-250° C. and the magnetic field in a range of 50-1000 Gauss.

19. The method of claim 11, wherein the diode emitter assembly emits at a power level that optically pumps the alkali vapor in the optical cell sufficient to result in an effective reduction of alkali number density moving two transmission peaks towards the atomic line center and has sufficient gain for both lines to lase simultaneously.

20. The method of claim 11, wherein the optical cell comprises two longitudinally aligned optical windows that are a selected one of: (i) anti-reflective coated; and (ii) Brewster angled to reduce optical losses.
